(19) United States
(12) Patent Application Publication
(10) Pub. No.: US 2020/0091304 A1
(43) Pub. Date: Mar. 19, 2020

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Mariko Yamashita, Yokohama Kanagawa (JP); Tomoko Kinoshita, Kamakura Kanagawa (JP); Keita Takahashi, Oita Oita (JP); Kanako Komatsu, Yokohama Kanagawa (JP)

(21) Appl. No.: 16/285,744

(22) Filed: Feb. 26, 2019

(30) Foreign Application Priority Data
Sep. 18, 2018 (JP) 2018-173787

(51) Int. Cl. H01L 29/423; H01L 29/06; H01L 21/265; H01L 21/266

(52) U.S. Cl. CPC H01L 29/4238; H01L 21/266; H01L 21/26513; H01L 29/0653

(57) ABSTRACT

A semiconductor device includes a semiconductor portion of a first conductivity type, an insulating portion provided in an upper layer portion of the semiconductor portion, a source region, a drain region and a gate electrode. The insulating portion surrounds an active area. The source region and the drain region are provided inside the active area and separated from each other along a first direction parallel to an upper surface of the semiconductor portion. The source region and the drain region are of a second conductivity type. The gate electrode is provided above the semiconductor portion. The gate electrode is disposed in a region directly above a region between the source region and the drain region, and disposed in a region directly above an end portion in a second direction of the active area. The second direction is orthogonal to the first direction.

### CROSS-REFERENCE TO RELATED APPLICATIONS

This application is based upon and claims the benefit of priority from Japanese Patent Application No. 2018-173787, filed on Sep. 18, 2018; the entire contents of which are incorporated herein by reference.

### FIELD

Embodiments relate to a semiconductor device.

### BACKGROUND

A MOSFET (Metal-Oxide-Semiconductor Field-Effect Transistor) may be formed in a semiconductor device by forming STI (Shallow Trench Isolation (an element-separating insulating film)) in an upper layer portion of a semiconductor substrate to partition an active area, and by providing a source region and a drain region inside the active area. It is desirable to increase the reliability of such a semiconductor device.

### BRIEF DESCRIPTION OF THE DRAWINGS

FIG. 1 is a plan view showing a semiconductor device according to a first embodiment;

FIG. 2 is a plan view showing the semiconductor device according to the first embodiment, and is a drawing in which a gate electrode is not illustrated;

FIG. 3 is a cross-sectional view along line A-A′ shown in FIG. 1;

FIG. 4 is a cross-sectional view along line B-B′ shown in FIG. 1;

FIG. 5 is a cross-sectional view along line C-C′ shown in FIG. 1;

FIG. 6 is a cross-sectional view showing a method for manufacturing the semiconductor device according to the first embodiment;

FIG. 7 is a plan view showing a semiconductor device according to a comparative example;

FIG. 8 is a cross-sectional view along line D-D′ shown in FIG. 7;

FIG. 9 is a plan view showing a semiconductor device according to a second embodiment; and

FIG. 10 is a plan view showing the semiconductor device according to the second embodiment, and is a drawing in which a gate electrode is not illustrated.

### DETAILED DESCRIPTION

A semiconductor device according to one embodiment includes a semiconductor portion of a first conductivity type, an insulating portion provided in an upper layer portion of the semiconductor portion, a source region, a drain region and a gate electrode. The insulating portion surrounds an active area. The source region and the drain region are provided inside the active area and separated from each other along a first direction parallel to an upper surface of the semiconductor portion. The source region and the drain region are of a second conductivity type. The gate electrode is provided above the semiconductor portion. The gate electrode is disposed in a region directly above a region between the source region and the drain region, and disposed in a region directly above an end portion in a second direction of the active area. The second direction is orthogonal to the first direction.

### First Embodiment

A first embodiment will now be described.

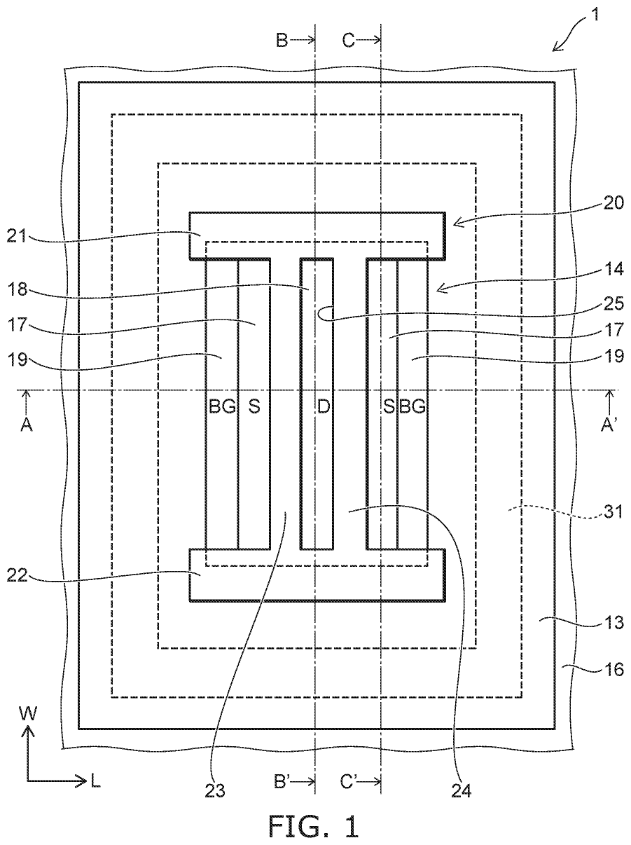

FIG. 1 is a plan view showing a semiconductor device according to the embodiment.

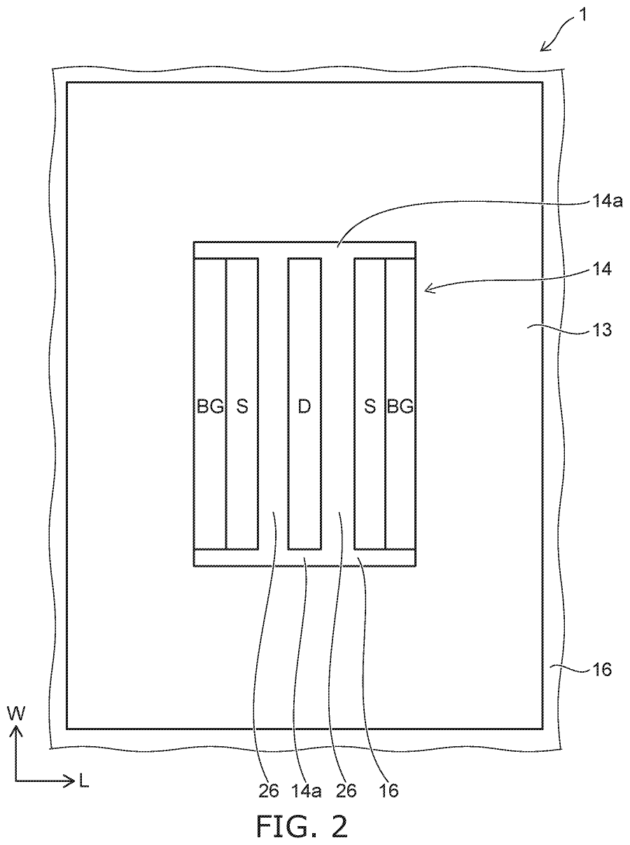

FIG. 2 is a plan view showing the semiconductor device according to the embodiment, and is a drawing in which the gate electrode is not illustrated.

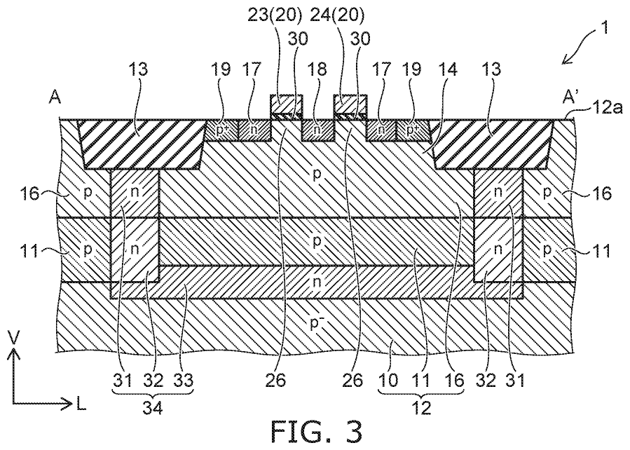

FIG. 3 is a cross-sectional view along line A-A′ shown in FIG. 1.

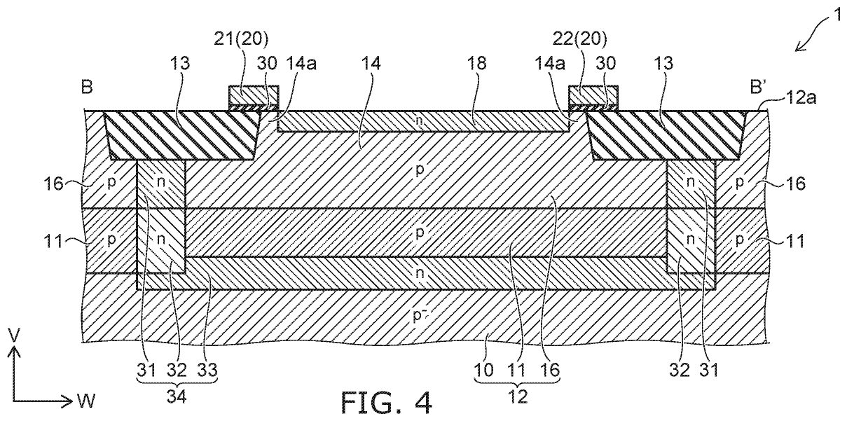

FIG. 4 is a cross-sectional view along line B-B′ shown in FIG. 1.

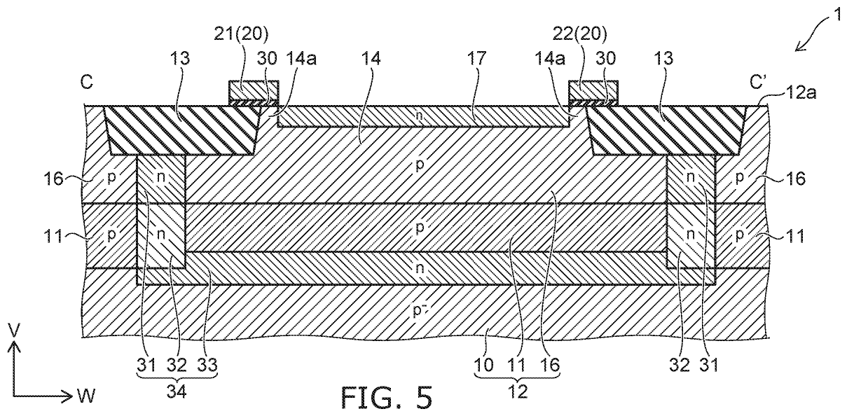

FIG. 5 is a cross-sectional view along line C-C′ shown in FIG. 1.

As shown in FIG. 1 to FIG. 5, a silicon substrate 10 of the p⁻-conductivity type is provided in the semiconductor device 1 according to the embodiment. An epitaxial layer 11 of the p-conductivity type is provided on the silicon substrate 10. The silicon substrate 10 and the epitaxial layer 11 are, for example, portions of a semiconductor portion 12 made of single-crystal silicon.

A STI 13 made of, for example, silicon oxide is provided in the upper layer portion of the epitaxial layer 11. When viewed from above, the configuration of at least a portion of the STI 13 is a frame-like configuration and partitions an active area 14. The active area 14 is a portion of the epitaxial layer 11 and is surrounded with the STI 13 when viewed from above. The upward direction is notated as a vertical direction V in the drawings.

A p-well 16 of the p-conductivity type is provided inside the active area 14. The p-well 16 is formed over substantially the entire region of the active area 14 and is disposed also below the STI 13.

Two source regions 17 of the n-conductivity type, one drain region 18 of the n-conductivity type, and two back gate regions 19 of the p⁺-conductivity type are provided in the upper layer portion of the p-well 16. The impurity concentrations of the source regions 17, the drain region 18, and the back gate regions 19 are higher than the impurity concentration of the p-well 16.

The configurations of the source regions 17, the drain region 18, and the back gate regions 19 when viewed from above (the vertical direction V) are band configurations extending in a gate-width direction W. In a gate-length direction L, the drain region 18 is disposed between the two source regions 17 and is separated from the source regions 17. The two back gate regions 19 are disposed on the outer sides of the two source regions 17 in the gate-length direction L. The back gate regions 19 contact the source regions 17.

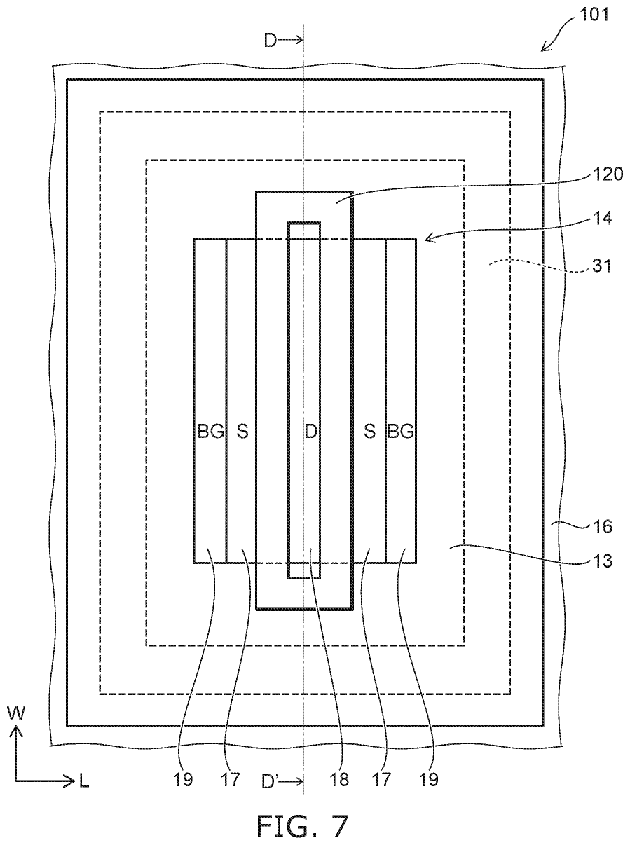

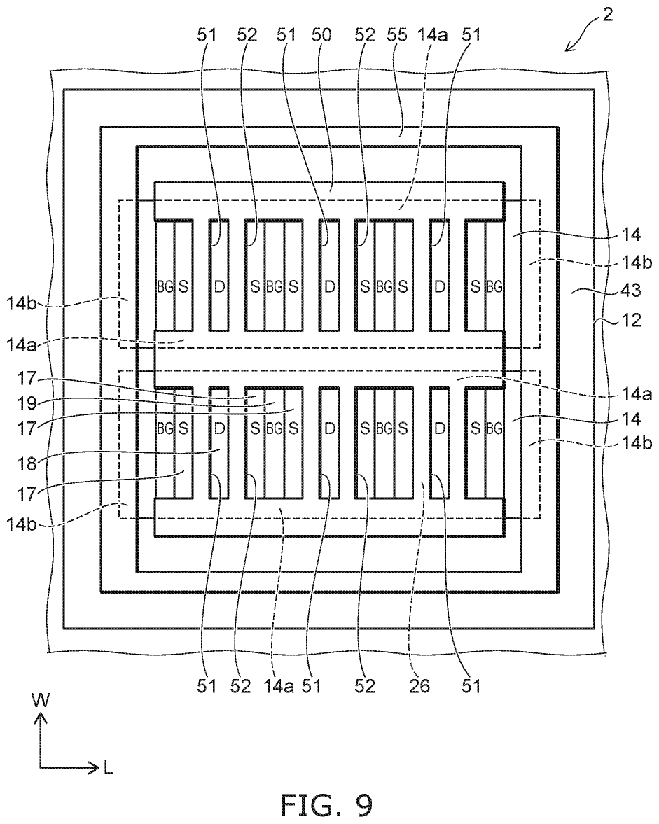

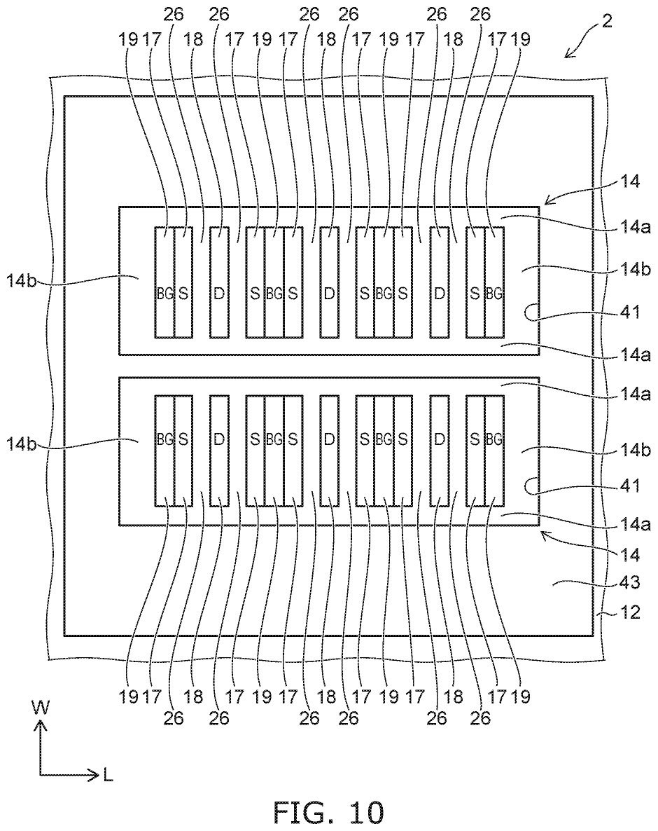

The p-well 16, the source region 17, the drain region 18, and the back gate region 19 also are portions of the semiconductor portion 12. The vertical direction V, the gate-width direction W, and the gate-length direction L are orthogonal to each other. An upper surface 12a of the semiconductor portion 12 as an entirety is parallel to the gate-width direction W and the gate-length direction L. In FIG. 1 and FIG. 2, the symbols of “S” for the source region 17, “D” for the drain region 18, and “BG” for the back gate region 19 are labeled for convenience. This is similar for FIG. 7, FIG. 9, and FIG. 10 described below as well.

A gate electrode 20 is provided on the semiconductor portion 12. A gate insulating film 30 is provided between the semiconductor portion 12 and the gate electrode 20. In the gate electrode 20, a pair of first portions 21 and 22 that extend in the gate-length direction L and a pair of second portions 23 and 24 that extend in the gate-width direction W are formed as one body. “The first portion 21 extending in the gate-length direction L” means that the length in the gate-length direction L of the first portion 21 is longer than the length in the gate-width direction W and the length in the vertical direction V of the first portion 21.

The first portion 21 and the first portion 22 are separated from each other in the gate-width direction W. The second portions 23 and 24 are disposed between the first portion 21 and the first portion 22. The second portion 23 and the second portion 24 are separated from each other in the gate-length direction L. The two end portions in the gate-width direction W of the second portions 23 and 24 are connected to the first portions 21 and 22. Thereby, an opening 25 that is surrounded with the first portion 21, the first portion 22, the second portion 23, and the second portion 24 is formed in the gate electrode 20.

The drain region 18 is disposed inside the opening 25 when viewed from above. The source region 17 and the back gate region 19 are disposed between the first portion 21 and the first portion 22 on the two sides in the gate-length direction L of the second portion 23, the opening 25, and the second portion 24.

A MOSFET formed of the p-well 16, the source region 17, the drain region 18, the back gate region 19, the gate electrode 20, and the gate insulating film 30. In such a case, the portion of the p-well 16 positioned between the source region 17 and the drain region 18 is used to form a channel region 26. The source region 17 and the back gate region 19 are connected to a common contact (not illustrated). The drain region 18 is connected to a drain contact (not illustrated). The gate electrode 20 is connected to a gate contact (not illustrated). The contacts are provided on the semiconductor portion 12. In the semiconductor device 1, two MOSFETs are formed by disposing one drain region 18 between two source regions 17.

The second portions 23 and 24 of the gate electrode 20 are disposed in regions directly above the channel regions 26. The first portions 21 and 22 are disposed from regions directly above end portions 14a in the gate-width direction W of the active area 14 to regions directly above the STI 13. In other words, the first portions 21 and 22 jut from the regions directly above the STI 13 toward the regions directly above the end portions 14a of the active area 14.

As shown in FIG. 4 and FIG. 5, the two end edges in the gate-width direction W of the source region 17, of the drain region 18, and of the back gate region 19 are positioned at regions substantially directly under the mutually-opposing end edges of the first portions 21 and 22 of the gate electrode 20. Therefore, the source region 17 and the drain region 18 are separated from the STI 13. Portions of the p-well 16 having impurity concentrations lower than those of the source region 17 and the drain region 18 are interposed between the source region 17 and the STI 13 and between the drain region 18 and the STI 13.

When viewed from above, an n-well 31 of the n-conductivity type is formed at the periphery of the p-well 16 in the semiconductor portion 12. The n-well 31 is disposed in a region directly under the STI 13 and contacts the lower surface of the STI 13. A portion of the n-well 31 pierces the STI 13 and is connected to a well contact (not illustrated). A deep n-well 32 of the n-conductivity type is provided below the n-well 31. A buried n-type layer 33 of the n-conductivity type is provided below the deep n-well 32 in a region directly under the active area 14. The buried n-type layer 33 is formed along the interface between the silicon substrate 10 and the epitaxial layer 11.

A box-shaped n-type region 34 is formed of the n-well 31, the deep n-well 32, and the buried n-type layer 33. The n-type region 34 surrounds surfaces of the active area 14 other than the upper surface of the active area 14, i.e., two side surfaces on the gate-length direction L side, two side surfaces on the gate-width direction W side, and the lower surface. The active area 14 is electrically isolated from the periphery by the STI 13 and the n-type region 34.

A method for manufacturing the semiconductor device according to the embodiment will now be described.

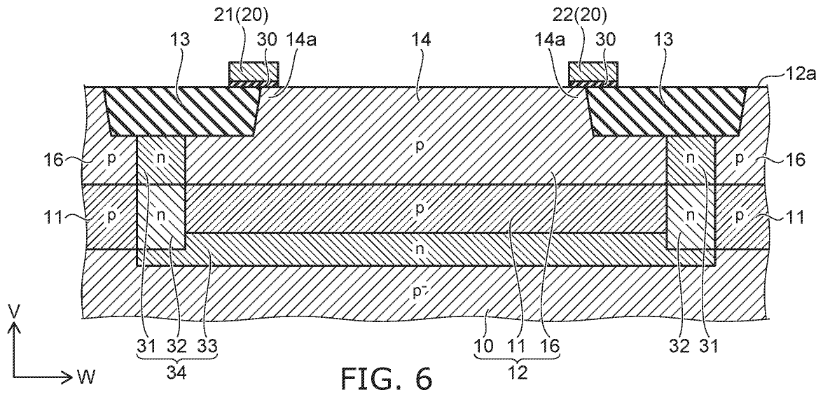

FIG. 6 is a cross-sectional view showing the method for manufacturing the semiconductor device according to the embodiment.

As shown in FIG. 6, the buried n-type layer 33 is formed in the upper layer portion of the silicon substrate 10 by ion implantation. Then, the epitaxial layer 11 is formed by epitaxially growing silicon on the upper surface of the silicon substrate 10. Then, the deep n-well 32 and the n-well 31 are formed by ion implantation; and the n-type region 34 is formed. Also, the p-well 16 is formed in the upper layer portion of the epitaxial layer 11. Then, the STI 13 is formed in the upper layer portion of the epitaxial layer 11. The STI 13 surrounds the active area 14 and partitions the active area 14.

Then, the gate insulating film 30 is formed at the upper surface of the epitaxial layer 11. Then, a polysilicon film is formed on the gate insulating film 30 and patterned with the gate insulating film 30. Thereby, the gate electrode 20 is formed. At this time, the first portions 21 and 22 of the gate electrode 20 are patterned to jut from the regions directly above the STI 13 toward the regions directly above the two end portions 14a in the gate-width direction W of the active area 14.

Continuing as shown in FIG. 4 and FIG. 5, ion implantation of impurities is multiply performed using the STI 13, the gate electrode 20, and a prescribed resist pattern (not illustrated) as a mask. The types of the implanted impurities, the conditions of the ion implantation, and the number of times of the ion implantation are different according to the necessary characteristics of the MOSFET. Thereby, the source region 17 and the drain region 18 are formed in the upper layer portion of the active area 14.

At this time, the first portions 21 and 22 of the gate electrode 20 jut from the regions directly above the STI 13 toward the regions directly above the two end portions 14a of the active area 14; therefore, the impurities substantially are not implanted into the two end portions 14a; and the source region 17 and the drain region 18 are formed in regions separated from the STI 13.

Then, the back gate region 19 is formed by ion implantation. When forming the back gate region 19 as well, the first portions 21 and 22 of the gate electrode 20 cover the two end portions 14a of the active area 14; therefore, the impurity substantially is not implanted into the two end portions 14a. Therefore, in the gate-width direction W, the back gate region 19 is formed in a region separated from the STI 13. Thus, the semiconductor device 1 according to the embodiment is manufactured.

Effects of the embodiment will now be described.

In the embodiment as shown in FIG. 6, FIG. 4, and FIG. 5, a portion of the gate electrode 20 covers the two end portions 14a of the active area 14 when performing the impurity implantation to form the source region 17, the drain region 18, and the back gate region 19. Therefore, the impurities are not implanted into the two end portions 14a; and the introduction of crystal defects due to the implantation of the impurities is suppressed. As a result, the occurrence of a leakage current caused by the crystal defects can be suppressed; and a semiconductor device can be realized in which the reliability is high.

Although an example is shown in the embodiment in which two MOSFETs are provided, the number of the MOSFETs may be one. Also, three or more MOSFETs may be formed as illustrated in the second embodiment described below.

### Comparative Example

A comparative example will now be described.

FIG. 7 is a plan view showing a semiconductor device according to the comparative example.

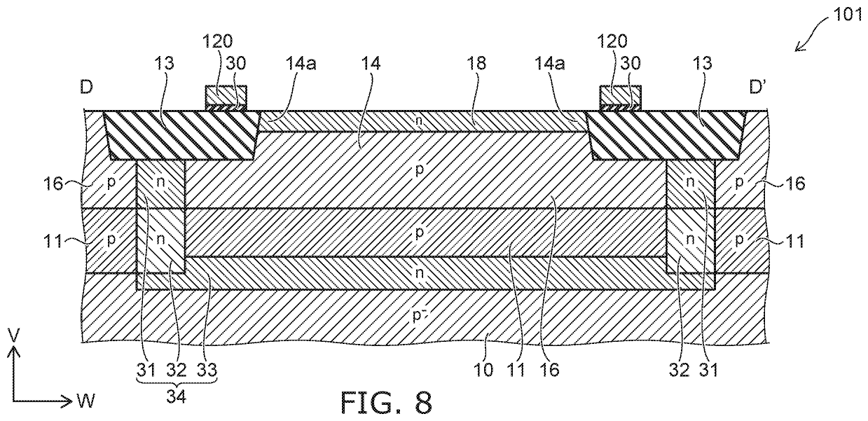

FIG. 8 is a cross-sectional view along line D-D′ shown in FIG. 7.

In the semiconductor device 101 according to the comparative example as shown in FIG. 7 and FIG. 8, the configuration of a gate electrode 120 when viewed from above is a frame-like configuration and does not cover the end portions in the gate-width direction W of the source region 17, the drain region 18, and the back gate region 19. Therefore, the source region 17, the drain region 18, and the back gate region 19 are formed over the total length in the gate-width direction W of the active area 14 and contact the STI 13.

Accordingly, in the semiconductor device 101, the impurities for forming the source region 17, the drain region 18, and the back gate region 19 are implanted into the end portions 14a in the gate-width direction W of the active area 14, i.e., the vicinity of the STI 13; and crystal defects are introduced easily. In particular, crystal defects are introduced easily at the interface vicinity of the STI 13.

In the semiconductor device 101, the crystal defects are terminated by the bonding of hydrogen in sintering performed in the manufacturing processes, etc.; therefore, it is often that problems do not become apparent directly after the completion of the semiconductor device 101. However, when stress such as a high temperature, a high voltage, or the like is applied, the hydrogen may desorb from the crystal defects; and a leakage current that has the crystal defects as starting points may occur. Therefore, the reliability of the semiconductor device 101 is low.

### Second Embodiment

A second embodiment will now be described.

FIG. 9 is a plan view showing a semiconductor device according to the embodiment.

FIG. 10 is a plan view showing the semiconductor device according to the embodiment and is a drawing in which the gate electrode is not illustrated.

The embodiment is an example in which many MOSFETs are formed in the semiconductor device.

In the semiconductor device 2 according to the embodiment as shown in FIG. 10, multiple openings 41 are formed in a STI 43 provided in the upper layer portion of the semiconductor portion 12. The active area 14 is disposed inside the openings 41. The active area 14 is partitioned by the STI 43. The multiple openings 41 are arranged along the gate-width direction W and are separated from each other. Although only two openings 41 are shown in FIG. 10, this is not limited thereto.

When viewed from above, the multiple source regions 17 are arranged to be separated from each other alternately along the gate-length direction L inside each of the openings 41. The drain region 18 is disposed in every other region between the mutually-adjacent source regions 17; and the back gate region 19 is disposed in every other region between the mutually-adjacent source regions 17. The back gate region 19 is disposed also on the outer side of the source region 17 on the outermost side. The drain region 18 is separated from the source regions 17 on the two sides of the drain region 18; and the region between the drain region 18 and the source region 17 is the channel region 26. The back gate region 19 contacts the source regions 17 on the two sides of the back gate region 19.

In the semiconductor device 2 as shown in FIG. 9, a gate electrode 50 and a gate electrode 55 are provided above the semiconductor portion 12. The configuration of the gate electrode 50 is a lattice configuration when viewed from above. The configuration of the gate electrode 55 is a frame-like configuration surrounding the gate electrode 50. The gate electrode 55 is separated from the gate electrode 50.

In the gate electrode 50, multiple openings 51 and 52 are arranged in a matrix configuration along the gate-width direction W and the gate-length direction L. The length in the gate-width direction W of the opening 51 is substantially equal to the length in the gate-width direction W of the opening 52. The length in the gate-length direction L of the opening 51 is shorter than the length in the gate-length direction L of the opening 52. The same types of openings are arranged in the gate-width direction W. The opening 51 and the opening 52 are arranged alternately in the gate-length direction L. One column that is made of the openings 51 and 52 arranged along the gate-length direction L corresponds to one opening 41 of the STI 43.

The drain region 18 is disposed inside the opening 51 when viewed from above. Two source regions 17 and one back gate region 19 that are disposed between the two source regions 17 are disposed inside the opening 52.

The portion of the gate electrode 50 extending along the gate-length direction L covers the greater part of the two end portions 14a in the gate-width direction W of the active area 14 and particularly covers the two sides in the gate-width direction W of each of the source region 17, the drain region 18, and the back gate region 19. Therefore, the source region 17, the drain region 18, and the back gate region 19 are separated from the STI 43. Also, the portions of the gate electrode 50 extending along the gate-width direction W are disposed in regions directly above the channel regions 26. On the other hand, the portions of the gate electrode 55 extending in the gate-width direction W cover two end portions 14b in the gate-length direction L of the active area 14.

In the embodiment as well, the greater part of the end portion 14a of the active area 14 is covered with the gate electrode 50. Also, the end portion 14b of the active area 14 is covered with the gate electrode 55. Thereby, little of the impurities for forming the source region 17, the drain region 18, and the back gate region 19 is implanted into the semiconductor portion 12 at the vicinity of the STI 43. As a result, the crystal defects are not introduced easily; and the reliability is high.

Otherwise, the configuration, the manufacturing method, and the effects of the embodiment are similar to those of the first embodiment.

The openings 41 of the STI 43 may be arranged in a matrix configuration along the gate-width direction W and the gate-length direction L.

Although an example is shown in the first and second embodiments in which an n-channel MOSFET is formed, a p-channel MOSFET may be formed.

According to the embodiments described above, a semiconductor device can be realized in which the reliability is high.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a semiconductor portion of a first conductivity type;
an insulating portion provided in an upper layer portion of the semiconductor portion, the insulating portion surrounding an active area;
a source region and a drain region provided inside the active area and separated from each other along a first direction parallel to an upper surface of the semiconductor portion, the source region and the drain region being of a second conductivity type;
a gate electrode provided above the semiconductor portion, disposed in a region directly above a region between the source region and the drain region, and disposed in a region directly above an end portion in a second direction of the active area, the second direction being orthogonal to the first direction.

2. The device according to claim 1, wherein the drain region is separated from the insulating portion.

3. The device according to claim 1, wherein the source region is separated from the insulating portion.

4. The device according to claim 1, wherein
the gate electrode includes:
a pair of first portions extending in the first direction; and
a second portion extending in the second direction, being provided between the pair of first portions, and being connected to the pair of first portions.

5. The device according to claim 1, wherein
a first opening is formed in the gate electrode, and
one of the source region or the drain region is disposed inside the first opening when viewed from above.

6. The device according to claim 5, wherein
a second opening is formed in the gate electrode and is separated from the first opening, and
the other of the source region or the drain region is disposed inside the second opening when viewed from above.

7. The device according to claim 6, wherein the first opening and the second opening are arranged alternately along the first direction.

8. The device according to claim 1, wherein a surface of the active area other than an upper surface of the active area is surrounded with a semiconductor region of the second conductivity type.

9. A semiconductor device, comprising:
a semiconductor portion of a first conductivity type;
an insulating member provided in an upper layer portion of the semiconductor portion, a plurality of first openings being formed in the insulating member and being separated from each other along a first direction;
a source region and a drain region provided inside each of the first openings and arranged alternately along a second direction orthogonal to the first direction, the source region and the drain region being of a second conductivity type; and
a gate electrode provided above the semiconductor portion, a plurality of second openings being formed in the gate electrode and being arranged in a matrix configuration along the first direction and the second direction,
the source region or the drain region being disposed inside the second opening when viewed from above,
the source region or the drain region disposed inside the second opening when viewed from above being separated from the insulating member.

10. The device according to claim 9, wherein
when viewed from above, the drain region is not disposed inside the second opening having the source region disposed in an interior of the second opening,
when viewed from above, the source region is not disposed inside the second opening having the drain region disposed in an interior of the second opening, and
the second opening having the source region disposed in the interior of the second opening and the second opening having the drain region disposed in the interior of the second opening are arranged alternately along the second direction.
